(19) United States
(12) Patent Application Publication
(10) Pub. No.: US 2025/0043418 A1
(43) Pub. Date: Feb. 6, 2025

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventors: Kazuki NONOMURA, Toyama-shi (JP); Arito Ogawa, Toyama-shi (JP)

(73) Assignee: Kokusai Electric Corporation, Tokyo (JP)

(21) Appl. No.: 18/746,924

(22) Filed: Jun. 18, 2024

(30) Foreign Application Priority Data
Aug. 1, 2023 (JP) 2023-125677

(51) Int. Cl. C23C 16/455; C23C 16/52; H01L 21/02

(52) U.S. Cl. CPC C23C 16/45534; C23C 16/45544; C23C 16/52; H01L 21/0228

(57) ABSTRACT

There is provided a technique that includes (a) supplying a first gas, which inhibits a second gas from adsorbing to a first adsorption site, to a substrate including a predetermined surface on which the first adsorption site exists; and (b) supplying the second gas to the substrate under a condition in which an amount of adsorption of the second gas on the predetermined surface becomes self-limiting, wherein (a) begins at the same time as (b) or before (b), and wherein the first gas has a larger amount of adsorption on the predetermined surface than the second gas.

### CROSS-REFERENCE TO RELATED APPLICATION

This application is based upon and claims the benefit of priority from Japanese Patent Application No. 2023-125677, filed on Aug. 1, 2023, the entire contents of which are incorporated herein by reference.

### TECHNICAL FIELD

The present disclosure relates to a method of processing a substrate, a method of manufacturing a semiconductor device, a substrate processing apparatus, and a recording medium.

### BACKGROUND

As a process of processing a substrate (processes of manufacturing a semiconductor device) in a related art, a process of forming a film on a surface of a substrate using a reaction inhibiting gas is carried out.

### SUMMARY

Some embodiments of the present disclosure provide a technique capable of improving uniformity of a film formed on a substrate surface.

According to one embodiment of the present disclosure, there is provided a technique that includes (a) supplying a first gas, which inhibits a second gas from adsorbing to a first adsorption site, to a substrate including a predetermined surface on which the first adsorption site exists; and (b) supplying the second gas to the substrate under a condition in which an amount of adsorption of the second gas on the predetermined surface becomes self-limiting, wherein (a) begins at the same time as (b) or before (b), and wherein the first gas has a larger amount of adsorption on the predetermined surface than the second gas.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, in which a portion of the process furnace is shown in a vertical cross-sectional view.

FIG. 2 is a schematic configuration diagram of the vertical process furnace of the substrate processing apparatus suitably used in the embodiments of the present disclosure, in which a portion of the process furnace is shown in a cross-section view taken along line A-A in FIG. 1.

FIG. 3 is a schematic configuration diagram of a controller of the substrate processing apparatus suitably used in the embodiments of the present disclosure, in which a control system of the controller is shown in a block diagram.

FIGS. 4A to 4C are partially-enlarged cross-sectional views showing examples of substances formed in each step of a processing sequence in the embodiments of the present disclosure.

FIG. 4A is a partially-enlarged cross-sectional view of a surface of a wafer after a first gas is adsorbed on the surface of the wafer.

FIG. 4B is a partially-enlarged cross-sectional view of the surface of the wafer after the first gas and a second gas are adsorbed on the surface of the wafer, to form a first layer.

FIG. 4C is a partially-enlarged cross-sectional view of the surface of the wafer after the first layer formed on the surface of the wafer is modified into a second layer by a third gas.

FIG. 5 is a partially-enlarged cross-sectional view of a film formed on the surface of the wafer in Modification 1 of the present disclosure.

FIGS. 6A to 6C are partially-enlarged cross-sectional views showing examples of substances formed in each step of a processing sequence in Modification 2 of the present disclosure.

FIG. 6A is a partially-enlarged cross-sectional view of the surface of the wafer after the first gas and the second gas are adsorbed on the surface of the wafer, to form the first layer.

FIG. 6B is a partially-enlarged cross-sectional view of the surface of the wafer after the first gas of the first and second gases adsorbed on the surface of the wafer is removed.

FIG. 6C is a partially-enlarged cross-sectional view of the surface of the wafer after a fourth gas is adsorbed on the surface of the wafer after the first gas is removed, to form a third layer.

FIG. 7 is a diagram showing a relationship between a supply time of the first gas per cycle and a concentration of a second element in a film when the film is formed using the processing sequence according to the embodiments of the present disclosure.

FIG. 8 is a diagram showing a relationship between a supply amount of the second gas per cycle and a concentration of a second element in a film when the film is formed using the processing sequence according to the embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### One Embodiment of the Present Disclosure

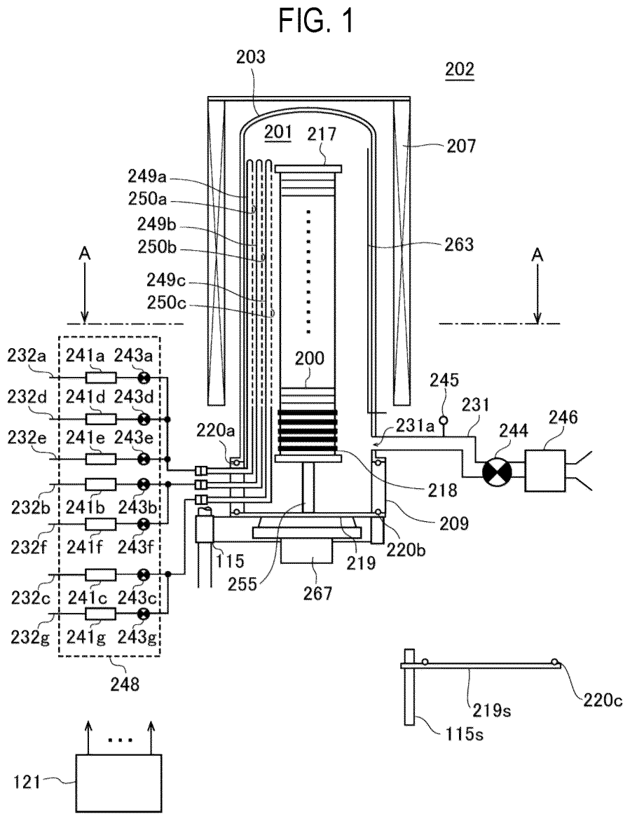

Embodiments of the present disclosure are now described mainly with reference to FIGS. 1 to 3 and 4A to 4C. The drawings used in the following description are schematic, and the dimensional relationships, ratios, and the like of respective elements shown in figures may not match the actual ones. Further, the dimensional relationships, ratios, and the like of respective elements between plural figures may not match each other.

### (1) Configuration of Substrate Processing Apparatus

As shown in FIG. 1, a process furnace 202 includes a heater 207 as a temperature adjustor (a heating system). The heater 207 is formed in a cylindrical shape and is supported by a holding plate so as to be vertically mounted. The heater 207 also functions as an activator (an exciter) configured to thermally activate (excite) a gas.

A reaction tube 203 is disposed inside the heater 207 to be concentric with the heater 207. The reaction tube 203 is made of, for example, a heat resistant material such as quartz (SiO₂) or silicon carbide (SiC), and is formed in a cylindrical shape with its upper end closed and its lower end opened. A manifold 209 is disposed to be concentric with the reaction tube 203 below the reaction tube 203. An upper end portion of the manifold 209 engages with a lower end portion of the reaction tube 203 so as to support the reaction tube 203. An O-ring 220a serving as a sealing member is provided between the manifold 209 and the reaction tube 203. Similar to the heater 207, the reaction tube 203 is vertically mounted. A process container (reaction container) mainly includes the reaction tube 203 and the manifold 209. A process chamber 201 is formed in a hollow cylindrical region of the process container. The process chamber 201 is configured to accommodate a plurality of wafers 200 as substrates. Processing of the wafers 200 is performed in the process chamber 201.

Nozzles 249a to 249c as first to third suppliers are provided in the process chamber 201 so as to penetrate through a sidewall of the manifold 209. The nozzles 249a to 249c are also referred to as first to third nozzles, respectively. The nozzles 249a to 249c are made of, for example, a heat resistant material such as quartz or SiC. Gas supply pipes 232a to 232c are connected to the nozzles 249a to 249c, respectively. The nozzles 249a to 249c are different nozzles, and each of the nozzles 249a and 249c is provided adjacent to the nozzle 249b.

The gas supply pipes 232a to 232c are respectively provided with mass flow controllers (MFCs) 241a to 241c, which are flow rate controllers (flow rate control parts), and valves 243a to 243c, which are opening/closing valves, sequentially from an upstream side of a gas flow. Each of gas supply pipes 232d and 232e is connected to the gas supply pipe 232a at a downstream side of the valves 243a. Gas supply pipes 232f and 232g are connected to the gas supply pipes 232b and 232c at downstream sides of the valves 243b and 243c, respectively. The gas supply pipes 232d to 232g are respectively provided with MFCs 241d to 241g and valves 243d to 243g, sequentially from an upstream side of a gas flow.

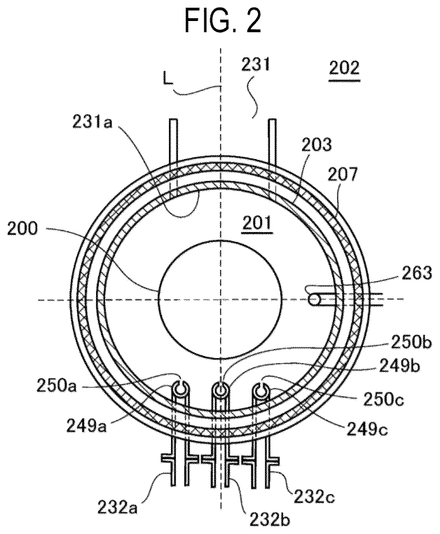

As shown in FIG. 2, each of the nozzles 249a to 249c is provided in an annular space (in a plane view) between an inner wall of the reaction tube 203 and the wafers 200, so as to extend upward from a lower portion of the inner wall of the reaction tube 203 to an upper portion thereof, that is, along an arrangement direction of the wafers 200. The nozzles 249a and 249c are disposed so as to sandwich a straight line L passing through the nozzle 249b and a center of the exhaust port 231a from both sides along the inner wall of the reaction tube 203 (an outer peripheral portion of the wafers 200). Each of gas supply holes 250a to 250c is opened so as to oppose (face) the exhaust port 231a in a plane view, enabling a gas to be supplied toward the wafers 200. A plurality of gas supply holes 250a to 250c are formed from a lower portion of the reaction tube 203 to an upper portion thereof.

A first gas is supplied from the gas supply pipe 232a into the process chamber 201 through the MFC 241a, the valve 243a, and the nozzle 249a. Herein, the first gas is a gas that inhibits a second gas and the like and a fourth gas and the like, which are described later, from adsorbing on the wafer 200, or inhibits the second gas and the like and the fourth gas and the like from adsorbing to a first adsorption site.

A third gas is supplied from the gas supply pipe 232b into the process chamber 201 through the MFC 241b, the valve 243b, and the nozzle 249b.

The fourth gas is supplied from the gas supply pipe 232c into the process chamber 201 through the MFC 241c, the valve 243c, and the nozzle 249c.

The second gas is supplied from the gas supply pipe 232d into the process chamber 201 through the MFC 241d, the valve 243d, the gas supply pipe 232a, and the nozzle 249a.

An inert gas is supplied from the gas supply pipes 232e to 232g into the process chamber 201 through the MFCs 241e to 241g, the valves 243e to 243g, the gas supply pipes 232a to 232c, and the nozzles 249a to 249c, respectively. The inert gas acts as a purge gas, a carrier gas, a dilution gas, or the like.

A first gas supply system mainly includes the gas supply pipe 232a, the MFC 241a, and the valve 243a. A third gas supply system mainly includes the gas supply pipe 232b, the MFC 241b, and the valve 243b. A fourth gas supply system mainly includes the gas supply pipe 232c, the MFC 241c, and the valve 243c. A second gas supply system mainly includes the gas supply pipe 232d, the MFC 241d, and the valve 243d. An inert gas supply system mainly includes the gas supply pipes 232e to 232g, the MFCs 241e to 241g, and the valves 243e to 243g.

Any of the above-described various supply systems or the entire supply systems may be configured as an integrated-type supply system 248 in which the valves 243a to 243g, the MFCs 241a to 241g, and so on are integrated. The integrated-type supply system 248 is connected to each of the gas supply pipes 232a to 232g. In addition, the integrated-type supply system 248 is configured such that operations of supplying various materials (various gases) into the gas supply pipes 232a to 232g, i.e., the opening/closing operation of the valves 243a to 243g, the flow rate regulating operation by the MFCs 241a to 241g, and the like are controlled by a controller 121 which is described later. The integrated-type supply system 248 is configured as an integral type or detachable-type integrated unit, and may be attached to and detached from the gas supply pipes 232a to 232g and the like on an integrated unit basis, so that maintenance, replacement, extension, etc. of the integrated-type supply system 248 may be performed on an integrated unit basis.

The exhaust port 231a for exhausting an internal atmosphere of the process chamber 201 is provided at a lower side of a sidewall of the reaction tube 203. As shown in FIG. 2, in a plane view, the exhaust port 231a is provided at a position opposing (facing) the nozzles 249a to 249c (the gas supply holes 250a to 250c) with the wafers 200 interposed therebetween. The exhaust port 231a may be provided from a lower portion of the sidewall of the reaction tube 203 to an upper portion thereof, that is, along a wafer arrangement region. An exhaust pipe 231 is connected to the exhaust port 231a. A vacuum exhauster, for example, a vacuum pump 246, is connected to the exhaust pipe 231 through a pressure sensor 245, which serves as a pressure detector (pressure detection part) for detecting a pressure inside the process chamber 201, and an auto pressure controller (APC) valve 244, which serves as a pressure regulator (pressure regulation part). The APC valve 244 is configured to perform or stop a vacuum-exhaust of an interior of the process chamber 201 by opening/closing the valve while the vacuum pump 246 is actuated. The APC valve 244 is also configured to regulate the pressure inside the process chamber 201 by adjusting an opening degree of the valve based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219, which serves as a furnace opening lid configured to hermetically seal a lower end opening of the manifold 209, is provided below the manifold 209. An O-ring 220b, which is a sealing member making contact with a lower end of the manifold 209, is provided on an upper surface of the seal cap 219. A rotator 267 configured to rotate a boat 217, which is described later, is installed below the seal cap 219. A rotary shaft 255 of the rotator 267 is connected to the boat 217 by passing through the seal cap 219. The rotator 267 is configured to rotate the wafers 200 by rotating the boat 217. The seal cap 219 is configured to be vertically moved up and down by a boat elevator 115, which is an elevator installed outside the reaction tube 203. The boat elevator 115 is configured as a transporter (transport mechanism) that loads/unloads (transports) the wafers 200 into/out of the process chamber 201 by moving the seal cap 219 up and down.

A shutter 219s, which serves as a furnace opening lid configured to hermetically seal the opening at the lower end of the manifold 209 in a state where the seal cap 219 is lowered and the boat 217 is unloaded from the process chamber 201, is provided below the manifold 209. An O-ring 220c, which is a sealing member making contact with the lower end of the manifold 209, is provided on an upper surface of the shutter 219s. The opening/closing operation (such as an elevating operation, rotating operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with centers of the wafers 200 aligned with one another. That is, the boat 217 is configured to arrange the wafers 200 to be spaced apart from each other. The boat 217 is made of, for example, a heat resistant material such as quartz or SiC. Heat insulating plates 218 made of, for example, a heat resistant material such as quartz or SiC are supported at a lower portion of the boat 217 in multiple stages. Herein, the notation of a numerical range such as “25 to 200 wafers” in the present disclosure means that a lower limit value and an upper limit value are included in the range. Therefore, for example, “25 to 200 wafers” means “25 or more wafers and 200 or fewer wafers.” The same applies to other numerical ranges.

A temperature sensor 263 serving as a temperature detector is installed in the reaction tube 203. Based on temperature information detected by the temperature sensor 263, a state of supplying electric power to the heater 207 is regulated such that an interior of the process chamber 201 achieves a desired temperature distribution. The temperature sensor 263 is provided along the inner wall of the reaction tube 203.

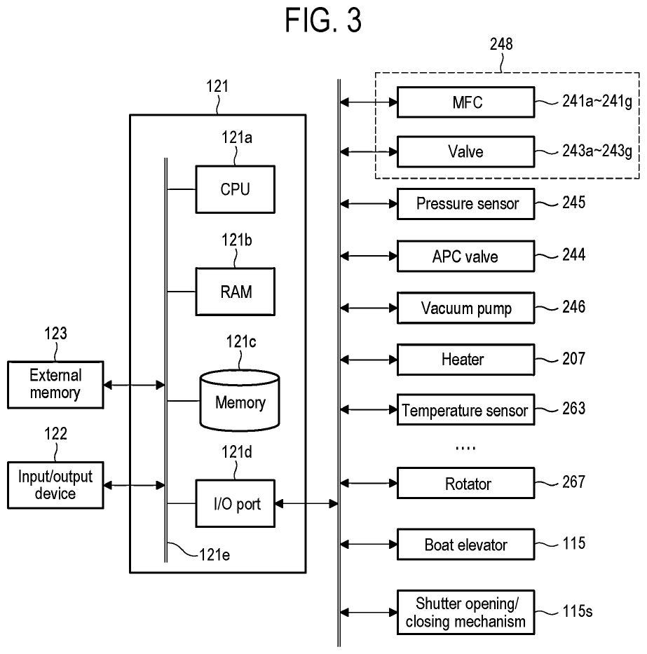

As shown in FIG. 3, a controller 121, which is a control part (control means), is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 formed of, e.g., a touch panel or the like, is connected to the controller 121. Further, an external memory 123 may be connected to the controller 121. Herein, the substrate processing apparatus may be configured to include one control part, or may be configured to include a plurality of control parts. That is, control for performing a substrate processing process to be described later may be performed using one control part, or may be performed using a plurality of control parts. Further, the plurality of control parts may be configured as a control system in which the plurality of control parts are connected to each other via a wired or wireless communication network, and the entire control system may perform control for performing the substrate processing process to be described later. When the term “control part” is used in the present disclosure, it may refer to a case of including one control part, a case of including a plurality of control parts or a case of a control system being configured by a plurality of control parts.

The memory 121c includes, for example, a flash memory, a hard disk drive (HDD), a solid state drive (SSD), or the like. A control program for controlling operations of a substrate processing apparatus, a process recipe in which sequences and conditions of substrate processing to be described later are written, etc. are readably recorded and stored in the memory 121c. The process recipe functions as a program that causes, by the controller 121, the substrate processing apparatus to execute each sequence in the substrate processing, which is described later, to obtain a predetermined result. Hereinafter, the process recipe and the control program may be generally and simply referred to as a “program.” Furthermore, the process recipe may be simply referred to as a “recipe.” When the term “program” is used herein, it may indicate a case of including the recipe, a case of including the control program, or a case of including both the recipe and the control program. The RAM 121b is configured as a memory area (work area) in which programs or data, etc. read by the CPU 121a are temporarily stored.

The I/O port 121d is connected to the MFCs 241a to 241g, the valves 243a to 243g, the pressure sensor 245, the APC valve 244, the vacuum pump 246, the temperature sensor 263, the heater 207, the rotator 267, the boat elevator 115, the shutter opening/closing mechanism 115s, and so on.

The CPU 121a is configured to read and execute the control program from the memory 121c. The CPU 121a is also configured to read the recipe from the memory 121c according to an input of an operation command from the input/output device 122. The CPU 121a is configured to control the flow rate regulating operations of various kinds of substances (gases) by the MFCs 241a to 241g, the opening/closing operations of the valves 243a to 243g, the pressure regulating operation performed by the APC valve 244 based on the opening/closing operation of the APC valve 244 and the pressure sensor 245, the actuating and stopping operation of the vacuum pump 246, the temperature regulating operation performed by the heater 207 based on the temperature sensor 263, the rotating of the boat 217 and adjusting a rotation speed of the boat 217 by the rotator 267, the operation of moving the boat 217 up and down by the boat elevator 115, the opening/closing operations of the shutter 219s by the shutter opening/closing mechanism 115s, and so on, according to contents of the read recipe.

The controller 121 may be configured by installing, on the computer, the aforementioned program recorded and stored in the external memory 123. Examples of the external memory 123 may include a magnetic disk such as a HDD, an optical disc such as a CD, a magneto-optical disc such as a MO, a semiconductor memory such as a USB memory or a SSD, and the like. The memory 121c or the external memory 123 is configured as a non-transitory computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Furthermore, the program may be provided to the computer by using communication means such as the Internet or a dedicated line, instead of using the external memory 123.

### (2) Substrate Processing Process

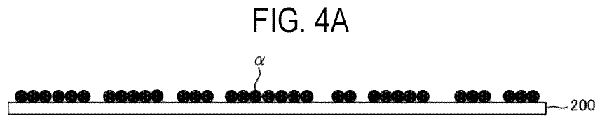

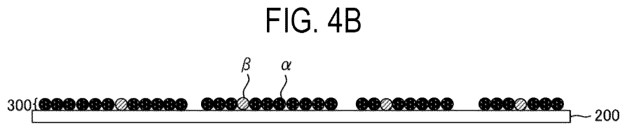

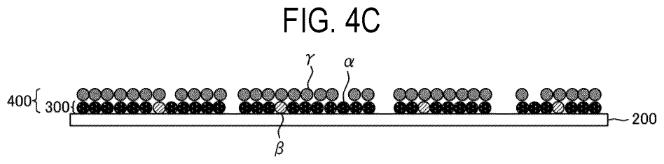

As a process of manufacturing a semiconductor device using the above-described substrate processing apparatus, an example of a method of processing a substrate, that is, a processing sequence for forming a film on a wafer 200 as a substrate, is described mainly with reference to FIGS. 4A to 4C. In the following description, the operations of the respective parts constituting the substrate processing apparatus are controlled by the controller 121.

A processing sequence in the present embodiments includes:
(a) supplying a first gas, which inhibits a second gas from adsorbing to a first adsorption site, to a wafer (200) including a predetermined surface on which the first adsorption site exists; and
(b) supplying the second gas to the wafer (200) under a condition in which an amount of adsorption of the second gas on the predetermined surface becomes self-limiting,
wherein (a) begins at the same time as (b) or before (b), and
wherein the first gas has a larger amount of adsorption on the predetermined surface than the second gas.

Further, a case will be described below in which the processing sequence further includes: (c) forming the first adsorption site on at least a portion of the predetermined surface, wherein a first cycle of performing (c) after (a) and (b) is performed a predetermined number of times (n times, where n is an integer greater than or equal to 1).

Further, a case will be described below in which in (c), a third gas is supplied to the wafer 200, to form the first adsorption site on at least a portion of the predetermined surface.

A case will be described in which the first gas includes a first element, the second gas includes a second element, and the third gas includes a third element.

In the present disclosure, for the sake of convenience, the above-described processing sequence may be denoted as follows. The same denotation may be used in modifications and other embodiments to be described later.

(First gas→Purge→Second gas→Purge→Third gas→Purge)×n

When the term “wafer” is used in the present disclosure, it may refer to “a wafer itself” or “a stacked body of a wafer and a predetermined layer or film formed on a surface of the wafer.” When the phrase “a surface of a wafer” is used in the present disclosure, it may refer to “a surface of a wafer itself” or “a surface of a predetermined layer formed on a wafer.” When the expression “a predetermined layer is formed on a wafer” is used in the present disclosure, it may mean that “a predetermined layer is formed directly on a surface of a wafer itself” or that “a predetermined layer is formed on a layer formed on a wafer.” When the term “substrate” is used in the present disclosure, it may be synonymous with the term “wafer.”

The term “agent” used in the present disclosure includes at least one selected from the group of a gaseous substance and a liquid substance. The liquid substance includes a mist-like substance. That is, each of a first precursor, a second precursor, and an oxidizing agent may include a gaseous substance, a liquid substance such as a mist-like substance, or both of them.

The term “layer” used in the present disclosure includes at least one selected from the group of a continuous layer and a discontinuous layer. For example, a first layer 300 and a second layer 400 to be described later may include a continuous layer, a discontinuous layer, or both of them.

In the present disclosure, when it is mentioned that each of a first gas, a second gas, a third gas, and a fourth gas adsorbs on or reacts with the surface of the wafer 200, it may include a manner in which they adsorb on or react with the surface of the wafer while they remain undecomposed, as well as a manner in which intermediates, produced by their decomposition or detachment of their ligands, adsorb on or react with the surface of the wafer 200.

### (Wafer Charging and Boat Loading)

After the boat 217 is charged with a plurality of wafers 200 (wafer charging), the shutter 219s is moved by the shutter opening/closing mechanism 115s and the lower end opening of the manifold 209 is opened (shutter open). Thereafter, as shown in FIG. 1, the boat 217 charged with the plurality of wafers 200 is lifted up by the boat elevator 115 to be loaded into the process chamber 201 (boat loading). In this state, the seal cap 219 seals the lower end of the manifold 209 via the O-ring 220b. Thus, the wafers 200 are prepared (provided) inside the process chamber 201.

Note that the wafers 200 with which the boat 217 is charged include a predetermined surface where the first adsorption site exists. In the embodiments, as an example, a case will be described in which the first adsorption site exists on a predetermined surface of the wafer 200. Note that the wafer 200 may include a surface where a substance different from the substance forming the predetermined surface is exposed.

### (Pressure Regulation and Temperature Regulation)

After the boat loading is completed, the interior of the process chamber 201, that is, a space where the wafers 200 are placed, is vacuum-exhausted (decompression-exhausted) by the vacuum pump 246 to reach a desired pressure (degree of vacuum). At this time, the pressure inside the process chamber 201 is measured by the pressure sensor 245, and the APC valve 244 is feedback-controlled based on the pressure information measured. Further, the wafers 200 in the process chamber 201 are heated by the heater 207 so as to reach a desired processing temperature. At this time, the state of supplying electric power to the heater 207 is feedback-controlled based on the temperature information detected by the temperature sensor 263 so that the interior of the process chamber 201 achieves a desired temperature distribution. Further, the rotation of the wafers 200 is initiated by the rotator 267. The exhaust of the interior of the process chamber 201 and the heating and rotation of the wafers 200 are continuously performed at least until the processing of the wafers 200 is completed.

### (Film Forming Process)

Thereafter, the following steps A, B, and C are performed sequentially.

### [Step A]

In this step, the first gas is supplied to the wafer 200 in the process chamber 201.

Specifically, the valve 243a is opened to allow the first gas to flow into the gas supply pipe 232a. The flow rate of the first gas is regulated by the MFC 241a. The first gas is supplied into the process chamber 201 through the nozzle 249a and is exhausted from the exhaust port 231a. In this operation, the first gas is supplied to the wafer 200 from the side of the wafer 200 (first gas supply). At this time, the valves 243e to 243g may be opened to allow an inert gas to be supplied into the process chamber 201 through the nozzles 249a to 249c, respectively.

A processing condition for supplying the first gas in this step is exemplified as follows:
Processing temperature: 350 to 700 degrees C., specifically 500 to 600 degrees C.
Processing pressure: 1 to 10,000 Pa, specifically 10 to 1,333 Pa
First gas supply flow rate: 0.01 to 3 slm, specifically 0.1 to 1 slm
First gas supply time: 10 to 120 seconds, specifically 20 to 60 seconds
Inert gas supply flow rate (for each gas supply pipe): 0 to 10 slm

In the present disclosure, the processing temperature means the temperature of the wafer 200 or the temperature inside the process chamber 201, and the processing pressure means the pressure inside the process chamber 201, in other words, the pressure of a space where the wafers 200 are placed. Further, the gas supply flow rate of 0 slm refers to a case where no gas (substance) is supplied. These apply equally to the following description.

By supplying the first gas to the wafer 200 under the above-mentioned processing condition, at least one or more selected from the group of the first gas, a substance containing a portion of a molecular structure of the first gas, and a first element contained in the first gas may be adsorbed to the first adsorption site existing on the surface of the wafer 200 (see FIG. 4A). Hereinafter, at least one or more selected from the group of the first gas, the substance containing a portion of the molecular structure of the first gas, and the first element contained in the first gas may be referred to as the first gas and the like. Note that in FIGS. 4A to 4C, the first gas and the like are indicated by a letter α.

This step is performed under a condition in which an amount of adsorption of the first gas on the surface of the wafer 200 becomes self-limiting such that the amount of adsorption of the first gas on the surface of the wafer 200 becomes unsaturated, which is preferable for the reasons to be described below. In the present disclosure, a condition in which an amount of adsorption of a gas becomes self-limiting is synonymous with a condition in which the amount of adsorption of the gas becomes self-restrictive or a condition in which the amount of adsorption of the gas asymptotically approaches a certain value. Specifically, this condition refers to a condition in which it may be assumed that as the gas supply time is lengthened, the amount of adsorption of the gas becomes saturated at a certain amount. Herein, regarding the amount of adsorption of the gas as being saturated at a certain amount is a concept including a case where the amount of adsorption of the gas is actually saturated, as well as a case where it is not actually saturated but becomes saturated over time (in the future). In addition, a condition in which the amount of adsorption of the first gas on the surface of the wafer 200 becomes unsaturated is specifically a condition in which the first gas is not adsorbed to the entire first adsorption site on the surface of the wafer 200, but the first adsorption site that adsorb the second gas supplied in step B, which is described later, remains.

As the inert gas, a nitrogen (N₂) gas or a rare gas such as an argon (Ar) gas, a helium (He) gas, a neon (Ne) gas, or a xenon (Xe) gas may be used. One or more of these gases may be used as the inert gas. This also applies to each step to be described later.

After the first gas is adsorbed on the surface of the wafer 200, the valve 243a is closed to stop the supply of the first gas into the process chamber 201. Then, the interior of the process chamber 201 is vacuum-exhausted to remove a gaseous substance and the like remaining in the process chamber 201 from the interior of the process chamber 201. At this time, the valves 243e to 243g are opened to allow an inert gas to be supplied into the process chamber 201 via the nozzles 249a to 249c. The inert gas supplied from the nozzles 249a to 249c acts as a purge gas, whereby the space where the wafers 200 are placed, that is, the interior of the process chamber 201, is purged (purging).

### [Step B]

After step A is completed, the second gas is supplied to the wafer 200 in the process chamber 201, that is, the wafer 200 with the first gas adsorbed on the surface of the wafer 200.

Specifically, the valve 243d is opened to allow the second gas to flow into the gas supply pipe 232d. The flow rate of the second gas is regulated by the MFC 241d. The second gas is supplied into the process chamber 201 through the nozzle 249a and is exhausted from the exhaust port 231a. In this operation, the second gas is supplied to the wafer 200 from the side of the wafer 200 (second gas supply). At this time, the valves 243e to 243g may be opened to allow an inert gas to be supplied into the process chamber 201 through the nozzles 249a to 249c, respectively.

A processing condition for supplying the second gas in this step is exemplified as follows:
Processing temperature: 20 to 700 degrees C., specifically 200 to 600 degrees C., more specifically 500 to 600 degrees C.
Processing pressure: 1 to 10,000 Pa, specifically 10 to 2,666 Pa, more specifically 1,000 to 2,666 Pa
Second gas supply flow rate: 0.01 to 4 slm, specifically 0.3 to 1 slm
Second gas supply time: 1 to 360 seconds, specifically 5 to 180 seconds

Other processing conditions may be the same as the one used when supplying the first gas in step A. However, this step is performed under a condition in which an amount of adsorption of the second gas on the surface of the wafer 200 where the first adsorption site exists becomes self-limiting.

By supplying the second gas to the wafer 200 under the above-mentioned processing condition, at least one or more selected from the group of the second gas, a substance containing a portion of a molecular structure of the second gas, and a second element contained in the second gas may be adsorbed at a location on the surface of the wafer 200 where the first gas and the like are not adsorbed, that is, to the first adsorption site remaining on the surface of the wafer 200. As a result, a first layer 300 containing the first element and the second element may be formed on the surface of the wafer 200 (see FIG. 4B). Hereinafter, at least one or more selected from the group of the first gas, the substance containing a portion of the molecular structure of the second gas, and the second element contained in the second gas may be referred to as the second gas and the like. Note that in FIGS. 4B and 4C, the second gas and the like are indicated by a letter β.

Herein, the first gas is a gas that inhibits the second gas from adsorbing to the first adsorption site. Therefore, as shown in FIG. 4B, the second gas and the like are not adsorbed on the first gas and the like on the surface of the wafer 200. Herein, “the second gas and the like not being adsorbed on the first gas and the like” in the present disclosure means to include a case where none of the second gas and the like are adsorbed on the first gas and the like, as well as a case where an extremely small amount of the second gas and the like are adsorbed on the first gas and the like, for example, a case where the second gas and the like are adsorbed on about 1%, preferably 1% or less, of the first gas and the like on the wafer 200.

By performing step A and step B, it is possible to adsorb the first gas and the like and the second gas and the like to the first adsorption site provided on the surface of the wafer 200, thereby forming the first layer 300 containing the first element and the second element (see FIG. 4B). In other words, it is possible to form the first layer doped with the second element. A predetermined adsorption site to which a third gas supplied in step C to be described later is adsorbed is formed on a surface of the first layer 300.

By performing step A and step B under the above-mentioned processing condition, the amount of adsorption of the first gas on the surface of the wafer 200 may be made larger than the amount of adsorption of the second gas on the surface of the wafer 200.

This step (step B) may be performed under a condition in which the amount of adsorption of the second gas on the surface of the wafer 200 is not saturated, or may be performed under a condition in which it is saturated. Note that the condition in which the amount of adsorption of the second gas on the surface of the wafer 200 is not saturated is specifically a condition in which the second gas is not entirely adsorbed to the first adsorption site remaining on the surface of the wafer 200.

After the first layer 300 is formed on the surface of the wafer 200, the valve 243d is closed to stop the supply of the second gas into the process chamber 201. Then, the interior of the process chamber 201 is vacuum-exhausted to remove a gaseous substance and the like remaining in the process chamber 201 from the interior of the process chamber 201. At this time, the valves 243e to 243g are opened to allow an inert gas to be supplied into the process chamber 201 through the nozzles 249a to 249c. The inert gas supplied from the nozzles 249a to 249c acts as a purge gas, whereby the space where the wafers 200 are placed, that is, the interior of the process chamber 201, is purged (purging).

### [Step C]

After step B is completed, the third gas is supplied to the wafer 200 in the process chamber 201, that is, the wafer 200 with the first layer 300 formed on the surface of the wafer 200.

Specifically, the valve 243b is opened to allow the third gas to flow into the gas supply pipe 232b. The flow rate of the third gas is regulated by the MFC 241b. The third gas is supplied into the process chamber 201 through the nozzle 249b and is exhausted from the exhaust port 231a. In this operation, the third gas is supplied to the wafer 200 from the side of the wafer 200 (third gas supply). At this time, the valves 243e to 243g may be opened to allow an inert gas to be supplied into the process chamber 201 through the nozzles 249a to 249c, respectively.

A processing condition for supplying the third gas in this step is exemplified as follows:
Processing temperature: 20 to 700 degrees C., specifically 200 to 600 degrees C., more specifically 500 to 600 degrees C.
Processing pressure: 100 to 10,000 Pa, specifically 1,000 to 10,000 Pa
Third gas supply flow rate: 0.1 to 20 slm, specifically 1 to 10 slm
Third gas supply time: 1 to 120 seconds, specifically 3 to 15 seconds

Other processing conditions may be the same as the one used when supplying the first gas in step A.

By supplying the third gas to the wafer 200 under the above-mentioned processing condition, the third gas and/or a third element contained in the third gas may be adsorbed on at least a portion of the first layer 300 formed on the surface of the wafer 200 (see FIG. 4C). Note that in FIG. 4C, the third gas and/or the third element contained in the third gas is indicated by a letter γ. Hereinafter, the third gas and/or the third element contained in the third gas may be referred to as the third gas and the like.

By supplying the third gas to the wafer 200 under the above-mentioned processing condition, at least a portion of the first layer 300 formed on the surface of the wafer 200 reacts with the third gas and is modified. As a result, a second layer 400, which is a modified layer of the first layer 300 and includes the first adsorption site, is formed on at least a portion of the surface of the wafer 200 (see FIG. 4C). The first adsorption site formed in this step functions as an adsorption site for the first gas and the second gas to be supplied in step A and step B of the next cycle.

After the second layer 400 is formed on the surface of the wafer 200, the valve 243b is closed to stop the supply of the third gas into the process chamber 201. Then, the interior of the process chamber 201 is vacuum-exhausted to remove a gaseous substance and the like remaining in the process chamber 201 from the interior of the process chamber 201. At this time, the valves 243e to 243g are opened to allow an inert gas to be supplied into the process chamber 201 through the nozzles 249a to 249c. The inert gas supplied from the nozzles 249a to 249c acts as a purge gas, whereby the space where the wafers 200 are placed, that is, the interior of the process chamber 201, is purged (purging).

### [Performing Predetermined Number of Times]

By performing a first cycle n times (n is an integer greater than or equal to 1), the first cycle including non-simultaneously, that is, without synchronization, performing the above-described steps A to C sequentially, a predetermined film is formed on the surface of the wafer 200. The above first cycle is preferably repeated a plurality of times. That is, for example, a thickness of the second layer 400 formed per cycle may be set to be smaller than a desired film thickness, and the above first cycle may be repeated a plurality of times until a thickness of the predetermined film formed by stacking second layers 400 reaches the desired film thickness.

In this embodiment, the first gas supplied in step A may be considered to be used as an adsorption inhibitor to inhibit a precursor of the above-mentioned predetermined film and the second gas supplied in step B from adsorbing to the first adsorption site and on the surface of the wafer 200. The second gas supplied in step B may be considered to be used as a dopant gas to form the above-mentioned predetermined film doped with the second element. The third gas supplied in step C may be considered to be used as a modifier to modify the first layer 300 formed by performing step A and step B into the second layer 400.

### (After-Purging and Returning to Atmospheric Pressure)

After the film forming process is completed, an inert gas acting as a purge gas is supplied into the process chamber 201 from each of the nozzles 249a to 249c and is exhausted from the exhaust port 231a. Thus, the interior of the process chamber 201 is purged and a gas, reaction by-products, and the like remaining in the process chamber 201 are removed from the process chamber 201 (after-purging). After that, the atmosphere inside the process chamber 201 is substituted with an inert gas (inert gas substitution) and the pressure inside the process chamber 201 is returned to the atmospheric pressure (returning to atmospheric pressure).

### (Boat Unloading and Wafer Discharging)

After that, the seal cap 219 is moved down by the boat elevator 115 to open the lower end of the manifold 209. Then, the processed wafers 200 supported by the boat 217 are unloaded from the lower end of the manifold 209 to an outside of the reaction tube 203 (boat unloading). After the boat unloading, the shutter 219s is moved and the lower end opening of the manifold 209 is sealed by the shutter 219s via the O-ring 220c (shutter close). The processed wafers 200 are unloaded from the reaction tube 203 and are then discharged from the boat 217 (wafer discharging).

### (3) Effects of the Present Embodiments

According to the present embodiment, one or more effects set forth below may be achieved.

(a) After the first gas is supplied in step A, the second gas is supplied in step B so that the amount of adsorption of the first gas on the surface of the wafer 200 is larger than the amount of adsorption of the second gas on the surface of the wafer 200. As a result, even if the amount of adsorption of the second gas is small relative to the number of first adsorption sites at the start of step A, it is possible to improve controllability of the amount of adsorption of the second gas and uniformity of the amount of adsorption of the second gas on the surface of the wafer 200. Further, by supplying the second gas in step B under the condition in which the amount of adsorption of the second gas on the surface of the wafer 200 becomes self-limiting, it is possible to improve the controllability of the amount of adsorption of the second gas. These are described below.

When the second gas is adsorbed to the first adsorption site existing on the surface of the wafer 200, as the amount of adsorption of the second gas gets smaller relative to the number of first adsorption sites, a difference between a location with a larger amount of adsorption of the second gas and a location with a smaller amount of adsorption of the second gas tends to become larger. In other words, the amount of adsorption of the second gas on the surface of the wafer 200 varies greatly. Therefore, the uniformity of the amount of adsorption of the second gas on the surface of the wafer 200 and the controllability of the amount of adsorption of the second gas tend to deteriorate.

In the embodiments, after the first gas is supplied in step A, the second gas is supplied in step B, and further, the amount of adsorption of the first gas on the surface of the wafer 200 is made larger than the amount of adsorption of the second gas on the surface of the wafer 200. That is, before step B is started, the first gas is adsorbed to a relatively large number of first adsorption sites among a plurality of first adsorption sites existing on the surface of the wafer 200. As a result, at the start of step B, since the number of first adsorption sites capable of adsorbing the second gas is reduced, it is possible to reduce the variations in the amount of adsorption of the second gas on the surface of the wafer 200. Further, the first gas is a gas that inhibits the second gas from adsorbing to the first adsorption site or on the predetermined surface. This makes it difficult for the second gas to adsorb on the first gas and the like adsorbed on the surface of the wafer 200. From the above, the second gas tends to preferentially adsorb to the first adsorption sites of the surface of the wafer 200 where the first gas and the like are not adsorbed. Therefore, in step B, it is possible to prevent the amount of adsorption of the second gas on the surface of the wafer 200 from exceeding a desired amount. As a result, it is possible to improve the uniformity of the amount of adsorption of the second gas on the surface of the wafer 200.

Further, in the embodiments, in step B, the second gas is supplied under the condition in which the amount of adsorption of the second gas on the surface of the wafer 200 becomes self-limiting. That is, the second gas is supplied under the condition in which it is possible to assume that the amount of adsorption of the second gas on the surface of the wafer 200 becomes saturated at a certain amount as the supply time of the second gas is lengthened. This makes it possible to prevent the amount of adsorption of the second gas on the surface of the wafer 200 from exceeding the desired amount in step B. As a result, it is possible to improve the controllability of the amount of adsorption of the second gas.

Further, when the second gas is adsorbed to the above-described first adsorption site, the tendency that the difference between a location with a larger amount of adsorption of the second gas and a location with a smaller amount of adsorption of the second gas becomes larger comes to be noticeable when the second gas is supplied from the side of the wafer 200 in step B. With the technique of the present disclosure, it is possible to improve the controllability of the amount of adsorption of the second gas and the uniformity of the amount of adsorption of the second gas on the surface of the wafer 200 even when the second gas is supplied from the side of the wafer 200.

(b) Step A is performed under the condition in which the amount of adsorption of the first gas on the surface of the wafer 200 becomes self-limiting such that the amount of adsorption of the first gas on the surface of the wafer 200 becomes unsaturated. This makes it easier to control the number of first adsorption sites where the first gas is not adsorbed in step A. As a result, it is possible to improve the controllability of the amount of adsorption of the second gas on the predetermined surface.

(c) Step B is performed under the condition in which the amount of adsorption of the second gas on the surface of the wafer 200 is not saturated, so that step B may be performed in a shorter time than when step B is performed under a condition in which the amount of adsorption of the second gas on the surface of the wafer 200 is saturated. As a result, it is possible to improve a throughput.

(d) By performing step A and step B, it is possible to form the first layer 300 on the surface of the wafer 200. More specifically, by performing step A and step B, it is possible to form the first layer 300 uniformly containing the first element and the second element on the surface of the wafer 200. Further, it is possible to improve controllability of the amount of the second element contained in the first layer 300.

(e) Since the second element is a different element from the first element, the first layer 300 uniformly containing the second element may be formed on the surface of the wafer 200.

Further, it is possible to improve the controllability of the amount of the second element contained in the first layer 300.

(f) By performing step C, it is possible to form the second layer 400 on the surface of the wafer 200. More specifically, by performing step C, a film containing the first element, the second element, and the third element, with a well-controlled amount of the contained second element, may be formed. In other words, it is possible to add the well-controlled amount of the second element to a film mainly composed of the first element and the third element.

Herein, as the first element, for example, one or more of tungsten (W), titanium (Ti), molybdenum (Mo), tantalum (Ta), cobalt (Co), yttrium (Y), ruthenium (Ru), hafnium (Hf), zirconium (Zr), aluminum (Al), silicon (Si), boron (B), gallium (Ga), indium (In), phosphorus (P), carbon (C), etc., may be used.

For example, as the third gas, a gas containing, for example, a reducing gas, an oxidizing gas, a nitriding gas, a sulfurizing gas, a selenide gas, a telluride gas, etc. may be used. One or more of these gases may be used as the third gas. For example, when the third gas is a reducing gas, a film composed of the first element and the second element may be formed on the wafer 200. For example, when the third gas is any one of an oxidizing gas, a nitriding gas, a sulfide gas, a selenide gas, and a telluride gas, an oxide film containing the first element and the second element, a nitride film containing the first element and the second element, a sulfide film containing the first element and the second element, a selenide film containing the first element and the second element, and a telluride film containing the first element and the second element may be formed on the wafer 200.

As the first gas, for example, a gas containing the above-described first element and a halogen element may be used. Examples of such a gas may include hexachlorotungsten (WCl₆), hexafluorotungsten (WF₆), titanium tetrachloride (TiCl₄), titanium tetrafluoride (TiF₄), molybdenum pentachloride (MoCl₅), molybdenum pentafluoride (MoF₅), molybdenum dioxide dichloride (MoO₂Cl₂), molybdenum oxide tetrachloride (MoOCl₄), tantalum pentachloride (TaCl₅), tantalum pentafluoride (TaF₅), cobalt difluoride (CoF₂), cobalt dichloride (CoCl₂), yttrium trifluoride (YF₃), yttrium trichloride (YCl₃), ruthenium trichloride (RuCl₃), ruthenium trifluoride (RuF₃), hafnium tetrachloride (HfCl₄), hafnium tetrafluoride (HfF₄), zirconium tetrachloride (ZrCl₄), zirconium tetrafluoride (ZrF₄), aluminum trichloride (AlCl₃), aluminum trifluoride (AlF₃), dichlorosilane (SiH₂Cl₂), 1,2-dichlorodisilane (Si₂H₄Cl₂), 1,1,1-trichlorodisilane (Si₂H₃Cl₃), 1,1,2-trichlorodisilane (Si₂H₃Cl₃), pentachlorodisilane (Si₂HCl₅), hexachlorodisilane (Si₂Cl₆), tetrafluorosilane (SiF₄), etc. Further, examples of the first gas may include monosilane (SiH₄), disilane (Si₂H₆), trisilane (Si₃H₅), tetrasilane (Si₄H₁₀), boron trifluoride (BF₃), boron trichloride (BCl₃), gallium trifluoride (GaF₃), gallium trichloride (GaCl₃), indium trifluoride (InF₃), indium trichloride (InCl₃), phosphorus trifluoride (PF₃), phosphorus pentafluoride (PF₅), phosphorus trichloride (PCl₃), phosphorus pentachloride (PCl₅), carbon tetrafluoride (CF₄), carbon tetrachloride (CCl₄), trifluoromethane (CHF₃), fluoromethane (CH₃F), trichloromethane (CHCl₃), chloromethane (CH₃Cl), etc.

In addition, as the first gas, for example, a gas containing the above-described first element and an organic ligand or a gas containing the above-described first element and a hydrogen group may be used. Examples of such a gas may include hexadimethylaminoditungsten (W₂[N(CH₃)₂]₆), bistertiarybutylimidebisdimethylamidetungsten((t-C₄H₉NH)₂W═(Nt-C₄H₉)₂), tetrakisethylmethylaminotitanium (Ti[N(C₂H₅)(CH₃)]₄), bisethylcyclopentadienylruthenium (Ru((CH₂CH₃)Cₚ)₂), biscyclopentadienylruthenium (Ru(Cp)₂), tetrakisethylmethylaminohafnium (Hf[N(CH₃)(CH₂CH₃)]₄), tetrakisdiethylaminohafnium (Hf[N(CH₂CH₃)₂]₄), tetrakisdimethylaminohafnium (Hf[N(CH₃)₂]₄), trisdimethylaminocyclopentadienylhafnium ((Cp)Hf[N(CH₃)₂]₃), tetrakisethylmethylaminozirconium (Zr[N(CH₃)Cp]₄), tetrakisdiethylaminozirconium (Zr[N(CH₂CH₃)₂]₄), tetrakisdimethylaminozirconium (Zr[N(CH₃)₂]₄), trisdimethylaminocyclopentadienylzirconium ((Cp)Zr[N(CH₃)₂]₃), trimethylaluminum (Al(CH₃)₃), trisdimethylaminosilane (Si[N(CH₃)₂]₃H), borane (BH₃), trimethylgallium (Ga(CH₃)₃), trimethylindium (In(CH₃)₃), phosphine (PH₃), methane (CH₄), etc.

Herein, as the second element, for example, one or more of the elements listed as examples of the first element may be used. Further, as the second gas, for example, a gas including one or more of the gases listed as examples of the first gas may be used.

As the reducing gas, for example, one or more of gases including a hydrogen (H₂) gas, a deuterium (D₂) gas, a borane (BH₃) gas, a diborane (B₂H₆) gas, a carbon monoxide (CO) gas, an ammonia (NH₃) gas, a monosilane (SiH₄) gas, a disilane (Si₂H₆) gas, a trisilane (Si₃H₅) gas, a monogermane (GeH₄) gas, a digermane (Ge₂H₆), etc. may be used. Further, as the reaction gas, for example, an oxidizing gas such as an oxygen(O)-containing gas may be used. As the oxidizing gas, for example, one or more of gases including oxygen (O₂), ozone (O₃), water vapor (H₂O), a mixed gas of H₂ and O₂, hydrogen peroxide (H₂O₂), nitrous oxide (N₂O), etc. may be used. As the nitriding gas, for example, one or more of hydrogen nitride-based gases such as an ammonia (NH₃) gas, a diazene (N₂H₂) gas, a hydrazine (N₂H₄) gas, and a N₃H₅ gas may be used. As the sulfide gas, for example, gases including sulfane (H₂S), disulfane (H₂S₂), diammonium sulfide ((NH₄)₂S), dimethylsulfide ((CH₃)₂S), etc. may be used. As the sulfide gas, one or more of these gases may be used. As the selenide gas, for example, gases including selane (H₂Se), diselane (H₂Se₂), dimethylselenium ((CH₃)₂Se), etc. may be used. As the selenide gas, one or more of these gases may be used. As the telluride gas, for example, gases including tellane (H₂Te), ditellane (H₂Te₂), dimethyltelluride ((CH₃)₂Te), etc. may be used. As the telluride gas, one or more of these gases may be used.

### (4) Modifications

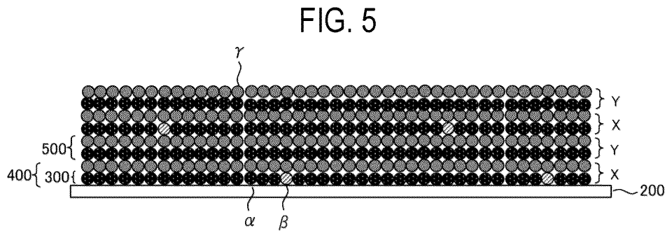

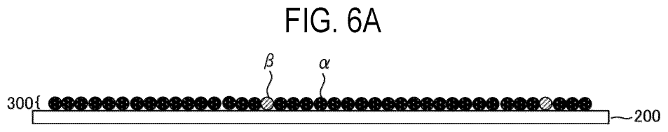

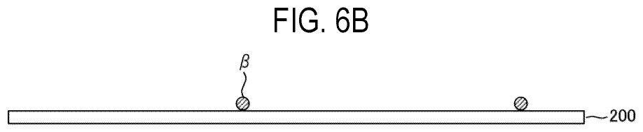

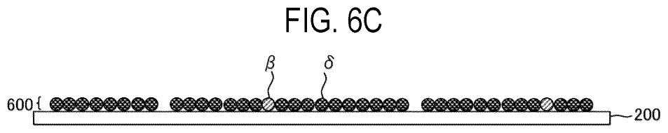

The substrate processing sequence in the present embodiments may be changed as in the following modifications. These modifications may be used in proper combination. Unless otherwise stated, the processing procedures and process condition in each step of each modification may be the same as the processing procedures and process condition in each step of the above-described substrate processing sequence. Hereinafter, in the configuration of a layer (film) formed on the surface of the wafer 200, which is described with reference to FIGS. 5 and 6A to 6C, elements that are different from those of the layer formed on the surface of the wafer 200 described with reference to FIGS. 4A to 4C are described, and substantially the same elements are denoted by the same reference numerals and the explanation thereof is omitted.

### Modification 1

As in the processing sequence shown below, a cycle may be performed a predetermined number of times (n₃ times, where n₃ is an integer greater than or equal to 1), wherein the cycle includes performing a first cycle a predetermined number of times (n₁ times, where n₁ is an integer greater than or equal to 1), and further performing a second cycle a predetermined number of times (n₂ times, where n₂ is an integer greater than or equal to 1), the first cycle including performing step C after step A and step B and the second cycle including performing step A and step C sequentially.

{(First gas→Purge→Second gas→Purge→Third gas→Purge)×n₁→(First gas→Purge Third gas→Purge)×n₂}×n₃

FIG. 5 shows, as an example, a layer (film) formed by performing the cycle twice, whereby the first cycle and the second cycle are each performed once in each cycle. In FIG. 5, the first cycle is indicated by a letter X, and the second cycle is indicated by a letter Y. In addition, in FIG. 5, a layer (second layer) formed by performing the first cycle is denoted by reference numeral 400, and a layer formed by performing the second cycle is denoted by reference numeral 500.

Also in this modification, the same effects as in the above-described embodiments or some of the effects may be obtained. Further, in this modification, it is possible to form a film with a low content of the second element by forming a layer 500 not containing the second element in addition to the second layer 400 containing the second element. For example, if the number of times of performance of the second cycle is increased compared to the number of time of performance of the first cycle, it is possible to form a film with a lower content of the second element than in the above-described embodiments.

Note that, as an example, FIG. 5 shows a case where the first adsorption site is formed on the entire surface of the second layer 400 in step C, but the present disclosure is not limited thereto, and the first adsorption site may be formed on a portion of the surface of the second layer 400. In this case as well, the same effects as in the above-described embodiments may be obtained. In this case, in step C, since the first adsorption site is formed on a portion of the surface of the second layer 400, the number of first adsorption sites on the surface of the second layer 400 may be reduced. As a result, in the next cycle, the first layer 300 with a lower content of the second element may be formed. As a result, it is possible to form a film with an even lower content of the second element.

### Modification 2

As in the processing sequence shown below, a cycle may be performed a predetermined number of times (m₁ times, where m₁ is an integer greater than or equal to 1), the cycle including performing step D of removing at least a portion of the first gas adsorbed on the surface of the wafer 200 after performing step A and step B.

(First gas→Purge→Second gas→Purge→First gas removal→Purge)×m₁

By performing step A and step B, the first gas and the like and the second gas and the like are adsorbed on the surface of the wafer 200, thereby forming the first layer 300 (see FIG. 6A). Thereafter, by performing step D, at least a portion of the first gas adsorbed on the surface of the wafer 200 is removed (see FIG. 6B). As step D, for example, a step of removing the first gas from the wafer 200 may be performed. The first gas may be removed by, for example, increasing the temperature of the wafer 200 to a temperature at which the first gas is desorbed from the wafer 200, or supplying a removing agent (for example, one or more of a reducing gas, an oxidizing gas, and a nitriding gas to be described later) to the wafer 200. Herein, as a processing condition for supplying the removal agent in this step, the processing condition for supplying the third gas in step C may be used.

Further, as in the processing sequence shown below, a cycle may be performed a predetermined number of times (m₂ times, where m₂ is an integer greater than or equal to 1), the cycle including performing step A, step B, and step D and further performing step E of supplying a fourth gas that contains a fourth element and is different from the first gas.

(First gas→Purge→Second gas→Purge→First gas removal→Purge→Fourth gas→Purge)×m₂

Herein, in this modification, as the fourth element, for example, one or more of the elements listed as examples of the first element may be used. Further, as the fourth gas, for example, a gas including one or more of the gases listed as examples of the first gas may be used.

In step E performed after step D is completed, the fourth gas supply system supplies the fourth gas to the wafer 200 in the process chamber 201, that is, the wafer 200 with the first gas removed and the second gas adsorbed on the surface thereof.

A processing condition for supplying the fourth gas in this step is exemplified as follows:
Processing temperature: 350 to 700 degrees C., specifically 500 to 600 degrees C.
Processing pressure: 1 to 10,000 Pa, specifically 10 to 1,333 Pa
Fourth gas supply flow rate: 0.01 to 3 slm, specifically 0.1 to 1 slm
Fourth gas supply time: 10 to 120 seconds, specifically 20 to 60 seconds Inert gas supply flow rate (for each gas supply pipe): 0 to 10 slm

By supplying the fourth gas to the wafer 200 under the above-mentioned processing condition, the fourth gas and/or the fourth element contained in the fourth gas may be adsorbed on a location on the surface of the wafer 200 where the second gas and the like are not adsorbed (see FIG. 6C). More specifically, by supplying the fourth gas to the wafer 200 under the above-mentioned processing condition, the fourth gas and the like may be adsorbed on the surface of the wafer 200, thereby forming a third layer 600 containing the second element and the fourth element (see FIG. 6C). Note that in FIG. 6C, the fourth gas and/or the fourth element contained in the fourth gas is indicated by a letter δ. Hereinafter, the fourth gas and/or the fourth element contained in the fourth gas may be referred to as the fourth gas and the like.

Also in this modification, the same effects as in the above-described embodiments or some of the effects may be obtained. Further, in this modification, by removing the first gas on the surface of the wafer 200 in step D, a layer containing the second element uniformly on the surface of the wafer 200 and not containing the first element may be formed (see FIG. 6B). Further, by supplying the fourth gas in step E, the third layer 600 uniformly containing the second element and the fourth element may be formed on the surface of the wafer 200 (see FIG. 6C). Further, it is possible to improve controllability of the amount of the second element contained in the third layer 600.

### Modification 3

As in the processing sequence shown below, a cycle may be performed a predetermined number of times (p₁ times, where p₁ is an integer greater than or equal to 1), the cycle including performing step A, step B, step E, and step C.

(First gas→Purge→Second gas→Purge→Fourth gas→Purge→Third gas→Purge)×p₁

Also in this modification, the same effects as in the above-described embodiments or some of the effects may be obtained. Further, in this modification, a layer containing the first element, the second element, the third element, and the fourth element is formed. This makes it possible to uniformly form a film containing the second element and the fourth element on the surface of the wafer 200. In other words, it is possible to add a well-controlled amount of the second element and the fourth element to a film mainly composed of the first element and the third element.

Further, as in the processing sequence shown below, a cycle may be performed a predetermined number of times (p₃ times, where p₃ is an integer greater than or equal to 1), wherein the cycle includes performing a cycle, performing step A, step B, and step C, a predetermined number of times (p₁ times, where p₁ is an integer greater than or equal to 1), and further performing a cycle, performing step A, step E, and step C sequentially, a predetermined number of times (p₂ times, where p₂ is an integer greater than or equal to 1).

{(First gas→Purge→Second gas→Purge→Third gas→Purge)×p₁→(First gas→Purge→Fourth gas→Purge→Third gas→Purge)×p₂}×p₃

Herein, in this modification, as the fourth element, for example, one or more of the elements listed as examples of the first element and different from the first element and the second element is used. Further, as the fourth gas, for example, a gas including one or more of the gases listed as examples of the first gas may be used.

Also in this modification, the same effects as in the above-described embodiments or some of the effects may be obtained. Further, in this modification, a layer containing the first element, the second element, and the third element and a layer containing the first element, the fourth element, and the third element are formed. This makes it possible to uniformly form a film containing the second element and the fourth element on the surface of the wafer 200. In other words, it is possible to add a well-controlled amount of the second element and the fourth element to a film mainly composed of the first element and the third element.

### Other Embodiments of the Present Disclosure

The embodiments of the present disclosure are specifically described above. However, the present disclosure is not limited to the above-described embodiments, and various changes may be made without departing from the gist thereof.

For example, when the amount of adsorption of the second gas on the surface of the wafer 200 is set to 0.001 to 30.0% of a total amount of adsorption of the first gas and adsorption of the second gas, the amount of adsorption of the second gas on the surface of the wafer 200 tends to vary greatly. Further, when the amount of adsorption of the second gas is set to 0.005 to 10.0% or less of the total amount of adsorption of the first gas and adsorption of the second gas, the amount of adsorption of the second gas on the surface of the wafer 200 tends to vary greatly. Further, when the amount of adsorption of the second gas is set to 0.010 to 5.0% of the total amount of adsorption of the first gas and adsorption of the second gas, the variation in the amount of adsorption of the second gas on the surface of the wafer 200 becomes noticeable. Even in these cases, it is possible to improve the controllability of the amount of adsorption of the second gas on the surface of the wafer 200 by using the technique of the present disclosure.

For example, in the above-described embodiments, an amount of the second gas adsorbed on the surface of the wafer 200 in step B may be controlled by a supply condition of the first gas in step A. The supply condition of the first gas refers to at least one or more selected from the group of, for example, a supply flow rate of the first gas, a supply time of the first gas, a partial pressure of the first gas in the process chamber 201 when the first gas is supplied, and a concentration (a ratio of the first gas and an inert gas) of the first gas in the process chamber 201. Also in these embodiments, the same effects as in the above-described embodiments may be obtained.

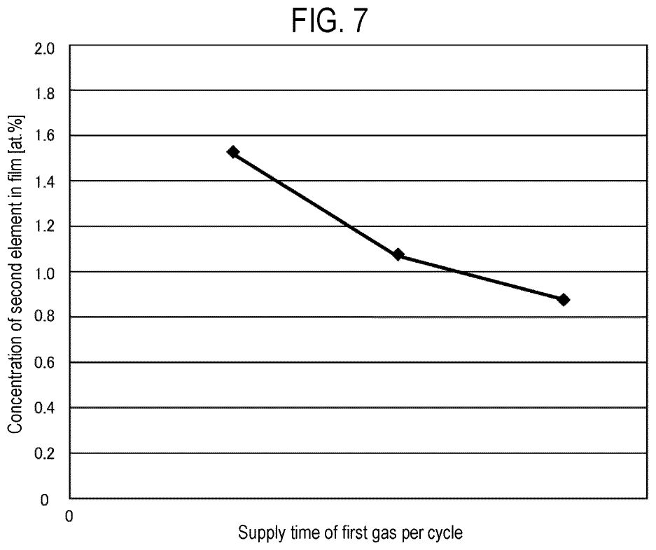

FIG. 7 is a graph showing a relationship between a supply time of the first gas in step A and a concentration of the second element in a film containing the first element, the second element, and the third element when the film is formed by the processing sequence described in the above-described embodiments. The horizontal axis of the graph in FIG. 7 represents the supply time of the first gas per cycle. The vertical axis of the graph in FIG. 7 represents the concentration of the second element in the film, and the unit of the concentration is [atom % (at. %)].

It may be seen from FIG. 7 that as the supply time of the first gas per cycle becomes longer and an amount of the first gas adsorbed to the first adsorption site increases, the concentration of the second element in the film becomes lower. As a result, when step A is performed under the condition in which the amount of adsorption of the first gas on the surface of the wafer 200 is unsaturated, the longer the supply time of the first gas in step A is, the smaller the amount of the second gas adsorbed on the surface of the wafer 200 in step B may be.

Similarly, in step A, the amount of the first gas adsorbed to the first adsorption site in step A increases in response to increasing the supply flow rate of the first gas, in response to increasing the partial pressure of the first gas in the process chamber 201 when the first gas is supplied, or in response to increasing the concentration of the first gas in the process chamber 201. Therefore, in these cases, the amount of the second gas adsorbed on the surface of the wafer 200 in step B is reduced. In this way, by controlling the amount of the first gas adsorbed to the first adsorption site according to the supply condition of the first gas in step A, it is possible to control the amount of the second gas adsorbed on the surface of the wafer 200 in step B.

Further, for example, in the above-described embodiments, the amount of the second gas adsorbed on the surface of the wafer 200 in step B may be controlled according to a supply condition of the second gas in step B. The supply condition of the second gas refers to at least one or more selected from the group of, for example, a supply flow rate of the second gas, a supply time of the second gas, a partial pressure of the second gas in the process chamber 201 when the second gas is supplied, and a concentration (a ratio of the second gas to an inert gas) of the second gas in the process chamber 201. Also in these embodiments, the same effects as in the above-described embodiments may be obtained.

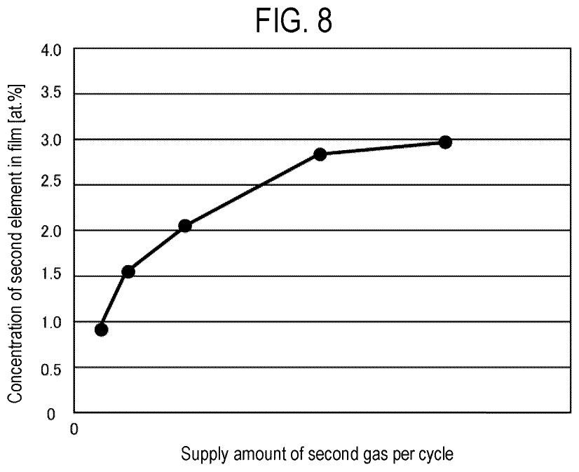

FIG. 8 is a graph showing a relationship between a supply flow rate of the second gas in step B and a concentration of the second element in a film containing the first element, the second element, and the third element when the film is formed by the processing sequence described in the above-described embodiments. The horizontal axis of the graph in FIG. 8 represents the supply amount of the second gas per cycle. The vertical axis of the graph in FIG. 8 represents the concentration of the second element in the film, and the unit of the concentration is [atom % (at. %)].

It may be seen From FIG. 8 that as the supply amount of the second gas per cycle increases and an amount of the second gas adsorbed to the first adsorption site increases, the concentration of the second element in the film increases. That is, as the supply amount of the second gas in step B increases, the amount of the second gas adsorbed on the surface of wafer 200 in step B may increase.

Similarly, in step B, the amount of the second gas adsorbed to the first adsorption site in step B increases in response to increasing the supply flow rate of the second gas, in response to increasing the partial pressure of the second gas in the process chamber 201 when the second gas is supplied, or in response to increasing the concentration of the second gas in the process chamber 201. Therefore, in these cases, the amount of the second gas adsorbed on the surface of the wafer 200 in step B increases. In this way, by controlling the amount of the second gas adsorbed to the first adsorption site according to the supply condition of the second gas in step B, it is possible to control the amount of the second gas adsorbed on the surface of the wafer 200 in step B.

For example, in the above-described embodiments, a case is described in which step B is performed under the condition in which the amount of adsorption of the second gas on the surface of the wafer 200 is not saturated. However, the present disclosure is not limited to such embodiments. For example, step B may be performed so as to adsorb the second gas to the entire first adsorption site where the first gas is not adsorbed. Also in these embodiments, the same effects as in the above-described embodiments may be obtained. In these embodiments, it is possible to further improve the controllability of the amount of adsorption of the second gas as compared to a case where the adsorption is performed under a non-saturated condition.

For example, in the above-described embodiments, a case is described as an example in which step A is started before step B. However, the present disclosure is not limited to such embodiments. For example, step A may be performed in part at the same time as step B, or step A may be started at the same time as step B. Also in this case, the same effects as in the above-described embodiments may be obtained.

Generally, when a hydrophilic ligand exists (a hydrophilic adsorption site is formed) on the surface of the wafer 200, it becomes difficult to adsorb a gas containing a hydrophilic ligand (hydrophilic gas) on the surface of the wafer 200. Similarly, when a hydrophobic ligand exists (a hydrophobic adsorption site is formed) on the surface of the wafer 200, it becomes difficult to adsorb a gas containing a hydrophobic ligand (hydrophobic gas) on the surface of the wafer 200. Herein, the hydrophilic ligand is a charged or highly-polar ligand, such as a halide (e.g., fluoride, chloride, bromide, iodide), an alkoxide group (e.g., —O(CH₃), —O(CH₂CH₃)), an amino group (e.g., —NH₂, —NH(CH₃), —N(CH₃)₂, —NH(CH₂CH₃), —N(CH₂CH₃)₂), etc. In addition, the hydrophobic ligand is an alkyl group (e.g., —CH₃, —CH₂CH₃), a hydrogen group (—H), a cycloalkyl group (e.g., —C₃H₅, —C₄H₇, —C₅H₉, —C₆H₁₁), a functional group containing a carbocyclic structure (e.g., a phenyl group (—C₆H₅), a cyclopentadienyl group (Cp)), etc.

From this, for example, in step A, when the first gas adsorbed to the first adsorption site forms a hydrophilic adsorption site on the surface of the wafer 200, it is preferable that the second gas supplied in step B is a hydrophilic gas. Further, in step A, when the first gas adsorbed to the first adsorption site forms a hydrophobic adsorption site on the surface of the wafer 200, it is preferable that the second gas supplied in step B is a hydrophobic gas. When any of these holds true, the first gas tends to inhibit the second gas and the like from adsorbing on the wafer 200, which makes it even more difficult for the second gas to adsorb on the first gas and the like adsorbed on the surface of the wafer 200. Accordingly, the second gas is more likely to preferentially adsorb to the first adsorption site of the surface of the wafer 200 where the first gas and the like are not adsorbed. Therefore, in step B, the amount of adsorption of the second gas on the surface of the wafer 200 becomes less likely to exceed a desired amount.

Herein, as the hydrophilic gas, for example, among the gases listed as examples of the first gas, those containing a hydrophilic ligand may be used. Further, as the hydrophilic gas, a gas containing a hydrophilic ligand may be used as appropriate, even if it is not listed as an example of the first gas. Similarly, as the hydrophobic gas, for example, among those listed as examples of the first gas, those containing a hydrophobic ligand can be used. As the hydrophobic gas, a gas containing a hydrophobic ligand may be used as appropriate, even if it is not listed as an example of the first gas.

For example, in the above-described embodiments, a case is described as an example in which the second element contained in the second gas is a different element from the first element contained in the first gas. However, the present disclosure is not limited to such embodiments. For example, the second element may be the same element as the first element, and the second gas may contain a different molecular structure from the first gas. Also in this case, the same effects as in the above-described embodiments may be obtained. Further, in this case, the first layer 300 containing the first element uniformly on the surface of the wafer 200 may be formed.

Recipes used in each process may be prepared individually according to the processing contents and may be stored in the memory 121c via a telecommunication line or the external memory 123. Moreover, at the beginning of each process, the CPU 121a may properly select an appropriate recipe from the recipes recorded and stored in the memory 121c according to the processing contents. Thus, it is possible for a single substrate processing apparatus to form films of various kinds, composition ratios, qualities, and thicknesses, with enhanced reproducibility. Further, it is possible to reduce an operator's burden and to quickly start each process while avoiding an operation error.

The recipes mentioned above are not limited to newly-prepared ones but may be prepared, for example, by modifying existing recipes that are already installed in the substrate processing apparatus. Once the recipes are modified, the modified recipes may be installed in the substrate processing apparatus via a telecommunication line or a recording medium storing the recipes. In addition, the existing recipes already installed in the existing substrate processing apparatus may be directly modified by operating the input/output device 122 of the substrate processing apparatus.

An example in which a film is formed using a batch-type substrate processing apparatus capable of processing a plurality of substrates at a time is described in the above-described embodiments. The present disclosure is not limited to the above-described embodiments, but may be suitably applied, for example, to a case where a film is formed using a single-wafer type substrate processing apparatus capable of processing a single substrate or several substrates at a time. In addition, an example in which a film is formed using a substrate processing apparatus provided with a hot-wall-type process furnace is described in the above-described embodiments. The present disclosure is not limited to the above-described embodiments, but may be suitably applied to a case where a film is formed using a substrate processing apparatus provided with a cold-wall-type process furnace.

Even in the case of using these substrate processing apparatuses, each process may be performed according to the same processing procedures and process condition as those in the above-described embodiments and modifications, and the same effects as those of the above-described embodiments and modifications may be obtained.

The above-described embodiments and modifications may be used in proper combination. The processing procedures and process conditions used in this case may be the same as, for example, the processing procedures and process conditions in the above-described embodiments and modifications.

According to the present disclosure in some embodiments, it is possible to improve uniformity of a film formed on a substrate surface.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) supplying a first gas, which inhibits a second gas from adsorbing to a first adsorption site, to the substrate including a predetermined surface on which the first adsorption site exists; and
(b) supplying the second gas to the substrate under a condition in which an amount of adsorption of the second gas on the predetermined surface becomes self-limiting,
wherein (a) begins at the same time as (b) or before (b), and
wherein the first gas has a larger amount of adsorption on the predetermined surface than the second gas.

2. The method of claim 1, wherein an amount of the second gas adsorbed on the predetermined surface in (b) is controlled by controlling a supply condition of the first gas in (a).

3. The method of claim 2, wherein (a) is performed under a condition in which an amount of adsorption of the first gas on the predetermined surface becomes self-limiting such that the amount of adsorption of the first gas on the predetermined surface becomes unsaturated.

4. The method of claim 1, wherein an amount of the second gas adsorbed on the predetermined surface in (b) is controlled by controlling a supply condition of the second gas in (b).

5. The method of claim 1, wherein (b) is performed under a condition in which the amount of adsorption of the second gas on the predetermined surface is not saturated.

6. The method of claim 1, wherein in (b), the second gas is adsorbed to the entire first adsorption site to which the first gas is not adsorbed.

7. The method of claim 1, wherein the first gas contains a first element, and the second gas contains a second element, and
wherein by (a) and (b), a first layer containing the first element and the second element is formed on the predetermined surface.

8. The method of claim 7, further comprising: (c) forming the first adsorption site on at least a portion of the predetermined surface,
wherein a first cycle of performing (c) after (a) and (b) is performed a predetermined number of times.

9. The method of claim 8, further comprising: performing a second cycle of performing (a) and (c) sequentially a predetermined number of times,
wherein each of the first cycle and the second cycle is performed a predetermined number of times.

10. The method of claim 7, wherein the second element is the same element as the first element, and
wherein the second gas has a molecular structure different from a molecular structure of the first gas.

11. The method of claim 8, wherein the second element is a different element from the first element.

12. The method of claim 8, wherein in (c), a third gas is supplied to the substrate to form the first adsorption site on at least a portion of the predetermined surface.

13. The method of claim 12, wherein the third gas contains a third element, and
wherein in (c), a second layer containing the third element and including the first adsorption site on a surface of the second layer is formed on at least a portion of the predetermined surface.

14. The method of claim 7, further comprising: (d) removing at least a portion of the first gas adsorbed on the predetermined surface.

15. The method of claim 14, further comprising: (e) supplying a fourth gas, which contains a fourth element and is different from the first gas, to form a third layer containing the second element and the fourth element on the predetermined surface.

16. The method of claim 1, wherein in (b), the second gas is supplied from a side of the substrate.

17. The method of claim 1, wherein (1) or (2) below holds true:
(1) the first gas adsorbed to the first adsorption site forms a hydrophilic adsorption site on the predetermined surface, and the second gas is a hydrophilic gas; and
(2) the first gas adsorbed to the first adsorption site forms a hydrophobic adsorption site on the predetermined surface, and the second gas is a hydrophobic gas.

18. A method of manufacturing a semiconductor device comprising the method of claim 1.

19. A substrate processing apparatus comprising:
a first gas supply system configured to supply a first gas, which inhibits a second gas from adsorbing to a first adsorption site, to a substrate including a predetermined surface on which the first adsorption site exists;
a second gas supply system configured to supply the second gas to the substrate; and
a controller configured to be capable of controlling the first gas supply system and the second gas supply system so as to perform a process including:
(a) supplying the first gas to the substrate; and
(b) supplying the second gas to the substrate under a condition in which an amount of adsorption of the second gas on the predetermined surface becomes self-limiting,
wherein (a) begins at the same time as (b) or before (b), and
wherein the first gas has a larger amount of adsorption on the predetermined surface than the second gas.

20. A non-transitory computer-readable recording medium storing a program that causes, by a computer, a substrate processing apparatus to perform a process comprising:
(a) supplying a first gas, which inhibits a second gas from adsorbing to a first adsorption site, to a substrate including a predetermined surface on which the first adsorption site exists; and
(b) supplying the second gas to the substrate under a condition in which an amount of adsorption of the second gas on the predetermined surface becomes self-limiting,
wherein (a) begins at the same time as (b) or before (b), and
wherein the first gas has a larger amount of adsorption on the predetermined surface than the second gas.
